(19) United States
(12) Patent Application Publication
(10) Pub. No.: US 2025/0079278 A1
(43) Pub. Date: Mar. 6, 2025

(54) LIQUID METAL SOCKET INTERCONNECTS WITH LIQUID PASSIVATION LAYER AND FILLER MATERIALS

(71) Applicant: Intel Corporation, Santa Clara, CA (US)

(72) Inventors: Karumbu Nathan Meyyappan, Portland, OR (US); Pooya Tadayon, Portland, OR (US); Ziyin Lin, Chandler, AZ (US); Gregory A. Stone, Hillsboro, OR (US)

(73) Assignee: Intel Corporation, Santa Clara, CA (US)

(21) Appl. No.: 18/460,406

(22) Filed: Sep. 1, 2023

(51) Int. Cl. H01L 23/498; H01L 23/00; H01L 23/538

(52) U.S. Cl. CPC H01L 23/49816; H01L 23/49827; H01L 23/5384; H01L 24/45; H01L 2224/45105

(57) ABSTRACT

In one embodiment, an apparatus comprises a substrate with conductive contacts on a first side of the substrate and a housing coupled to the first side of the substrate. The housing defines a set of holes around the conductive contacts. The apparatus further includes Gallium-based liquid metal in each hole, with the liquid metal being in contact with the conductive contact of the hole. The apparatus further includes a passivation layer on a surface of the liquid metal in each hole, the passivation layer being on an opposite end of the hole from the conductive contact in the hole.

### BACKGROUND

Liquid metal (LM) interconnect architectures may utilize Gallium (Ga) or Ga alloy liquid metals to provide separable and reusable interconnections for integrated circuit devices, e.g., in lieu of traditional solder-based interconnection technologies (e.g., ball grid arrays) that are substantially permanent in their current implementations.

### BRIEF DESCRIPTION OF THE DRAWINGS

FIGS. 1A-1B illustrate example integrated circuit device assemblies that utilizes a liquid metal (LM) socket interconnect in accordance with embodiments of the present disclosure.

FIG. 2A illustrates an example LM well implementation in current LM socket interconnects.

FIG. 2B illustrates an example LM well implementation in accordance with embodiments of the present disclosure.

FIG. 3 illustrates an example process for manufacturing an integrated circuit device assembly that utilizes a liquid metal (LM) socket interconnect in accordance with embodiments of the present disclosure.

FIG. 4 illustrates another example process for manufacturing an integrated circuit device assembly that utilizes a LM socket interconnect in accordance with embodiments of the present disclosure.

FIG. 5 is a top view of a wafer and dies that may be included in a microelectronic assembly, in accordance with any of the embodiments disclosed herein.

FIG. 6 is a cross-sectional side view of an integrated circuit device that may be included in a microelectronic assembly, in accordance with any of the embodiments disclosed herein.

FIG. 7 is a block diagram of an example electrical device that may include a microelectronic assembly, in accordance with any of the embodiments disclosed herein.

### DETAILED DESCRIPTION

Embodiments herein include integrated circuit device assemblies that utilize liquid metal (LM) socket interconnects. The LM socket interconnects may utilize metal pads on the backside of a package substrate along with a LM alloy, e.g., a Gallium (Ga)-based LM alloy, in an interposer device to provide a low insertion force and low contact resistance interface between the package and a socket on a main board (e.g., a motherboard). In certain architectures, the LM is filled into a well that is attached to an integrated circuit package. A socket may have pins that are inserted into the wells when the package is attached, causing the pins and LM to be in physical contact (and thus, electrical connection) with one another. The package can later be removed to allow for attachment to another socket, or to allow for another package to be attached to the same socket (e.g., when the package is defective).

However, current implementations when the package is detached, the LM can stick to the pins and come out of the wells within the package. In addition, in some instances, the LM can form an oxide layer on its top surface when exposed to certain atmospheric conditions, e.g., high humidity conditions. Previous solutions for these issues have involved the use of a sealant to minimize moisture diffusion into the package and/or a specifically formulated cap layer to contain the LM inside the wells. However, these are expensive and/or limited solutions, as they can cause implementation challenges and/or supply chain issues to the manufacturing process. Furthermore, current implementations may require relatively large wells to ensure proper electrical connections between the socket pins, the LM, and package pads (e.g., because of alignment or other potential issues when being attached). This large well volume requires a large amount of LM to fill the wells, but the LM can be an expensive material.

Accordingly, embodiments herein may implement a liquid passivation layer in the well (e.g., as an outer layer of the well) to prevent these or other issues. The layer can be formed from an oil-based material, such as mineral oil, paraffinic oil, Polyalphaolefin oil, or similar oil-based materials, or a wax-based material, such as paraffin wax. Implementation of a liquid passivation layer as described herein can eliminate the adverse reactions described above with respect to humid environments. In addition, the passivation layer can also prevent LM from sticking to the pins when removed from the socket, as the layer can “self-seal” the well as the socket pin is withdrawn. The use of a passivation layer can also reduce the amount of LM needed within the wells. Further, some embodiments may also include inert filler materials within the LM well that can allow for reduced LM usage, providing cost savings. The inert materials can, in some embodiments, also provide other advantages as well. For instance, the inert material can be a desiccant that absorbs moisture and prevents the issues described above in humid environments.

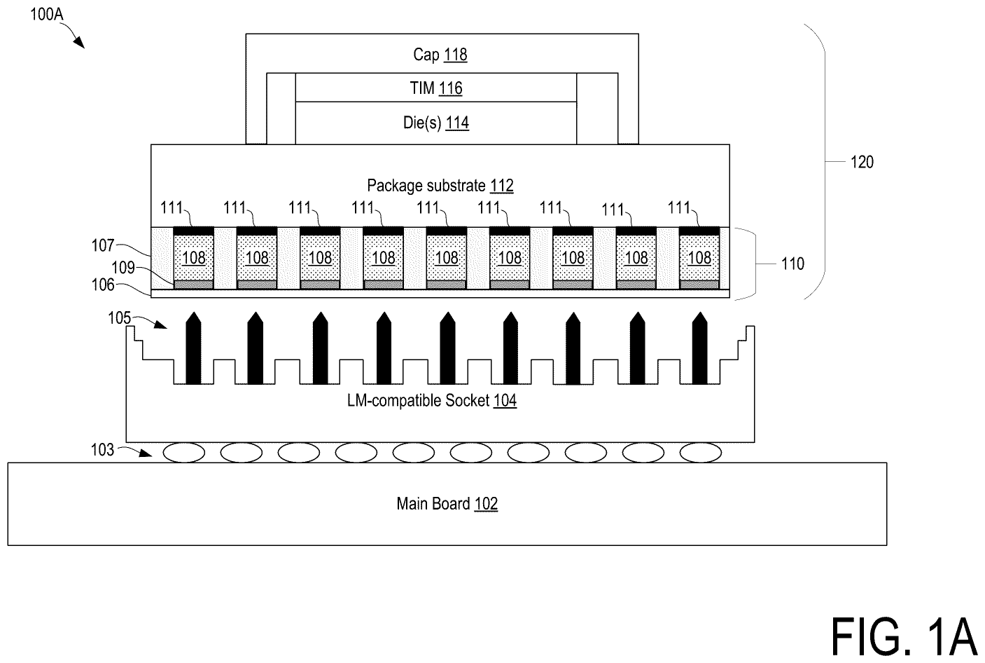

FIGS. 1A-1B illustrate example integrated circuit device assemblies 100A, 100B that utilizes a liquid metal (LM) interconnect in accordance with embodiments of the present disclosure. In the example shown, the assembly 100 includes a main board 102, which may be a motherboard, system board, etc. The main board 102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the main board 102. In other embodiments, the main board 102 may be or include a non-PCB substrate.

A LM-compatible socket 104 is coupled to the main board 102 via bumps 103. The bumps 103 may be formed using Tin or any other suitable bump material. In some embodiments, the LM-compatible socket 104 may be coupled to the main board 102 via other mechanisms.

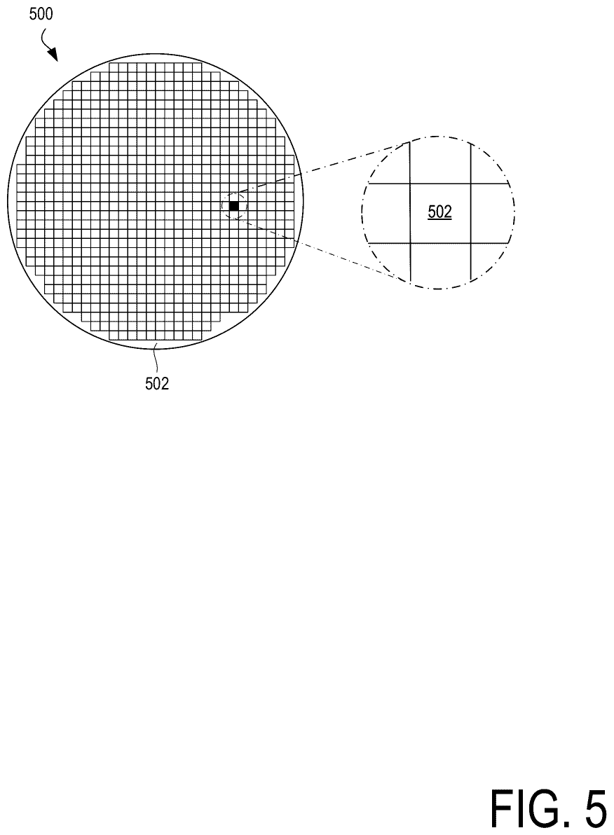

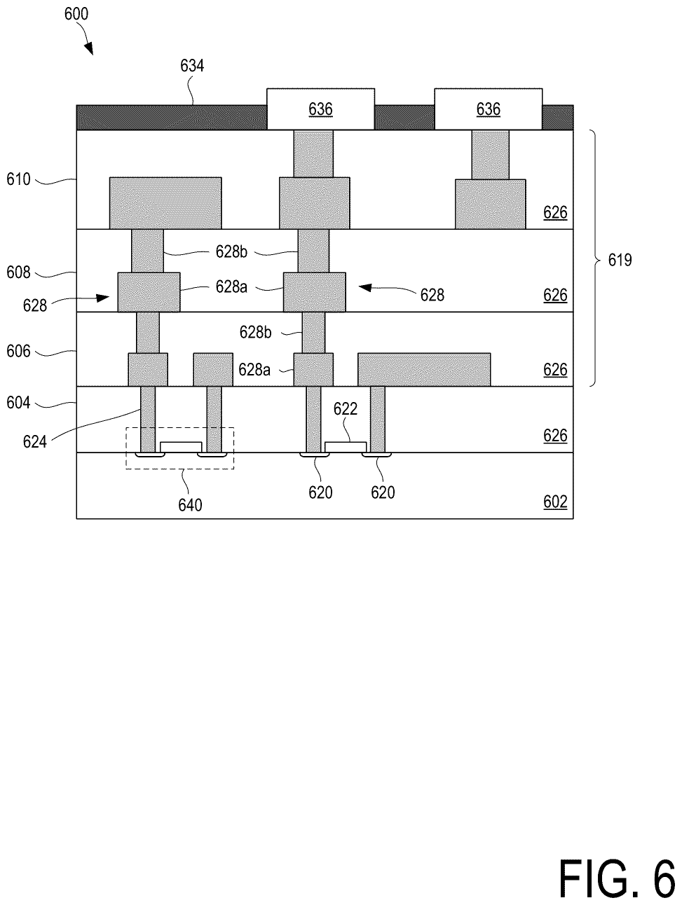

The assembly 100 also includes a package 120 that includes a package substrate 112, an integrated circuit die 114 on the package substrate 112, a thermal interface material (TIM) 116 on the die 114, and a cap 118 enclosing the die 114 and TIM 116 on the top surface of the package substrate 112. The die 114 may be a packaged or unpacked integrated circuit product that includes one or more integrated circuit dies (e.g., the die 502 of FIG. 5, the integrated circuit device 600 of FIG. 6) and/or one or more other suitable components. The die 114 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 114 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 114 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

The package 120 also includes an interposer 110, which includes a layer 107 with holes therein that define LM reservoirs or wells 108 (in which LM resides, e.g., a Ga-based LM), and a barrier 106 to prevent the LM from leaving the wells 108. The package substrate 112 includes a set of metal contact pads 111 formed on the backside of the substrate, i.e., on the side opposite from the die 114. The metal pads 111 allow for electrical connections between the main board 102 and the die 114, via the socket 104, the LM in the wells 108 of the interposer 110, and traces within the package substrate 112. In addition, there may be solder bumps on the metal pads 111 and in contact with the LM in the wells 108 of the interposer 110.

As shown, the LM-compatible socket 104 includes a set of interconnect pins 105 that include sharp ends as shown in FIGS. 1A-1B. The pins 105 enable an electrical connection between the main board 102 and the die 114 (through the LM in wells 108, pads 111, and conductive paths in the package substrate 112). The sharp ends of the interconnect pins 105 may be useful in piercing the barrier 106 of the interposer 110, causing the pins 105 to be in physical contact with the LM in the wells 108, and to thus be in electrical contact with the metal pads 111 of the package substrate 112.

In some cases, the interposer 110 may be designed to accommodate a variety of package and socket pin height variations. These variations must accordingly be accommodated by the fill height of the LM within the wells 108 of the interposer 110. Further, a substrate warpage tolerance, e.g., 300 um, may be designed around, which can cause further height of the wells 108. This can increase the cost of the overall interposer/package design. For instance, consider that a package and socket warped to approximately 200 um, up to 35% of the cost of the package may be driven by the cost of the LM in the wells. This cost can be largely driven by the raw material cost of the constituent LM materials (e.g., Gallium). Thus, as described above, certain embodiments may implement inert filler materials along with the LM within the wells 108 to reduce the amount of LM used and thus, the cost of the package. The filler material can also be chosen to provide other benefits as well, such as reduction of moisture in the environment.

Additionally, there can be challenges with the currently proposed solutions when a package is detached from the socket, as repeated insertion/removal of the socket pins can damage any solid/porous material used as the barrier 106. Thus, embodiments herein may utilize a passivation layer (e.g., 109) inside the well that can allow for self-healing. In addition, the passivation layer can act as additional material in the well, allowing for a reduction in the total amount of LM needed, further reducing costs. Moreover, as described above, LM can form a passivating oxide layer when exposed to certain atmospheric conditions. This oxide may be stable at higher temperatures and most conditions. However, in some scenarios, it may be desirable to protect against moisture that can affect the LM material. The use of a passivation layer (which can be approximately a few nm) over the LM in the well can help to eliminate any potential reactions with moisture.

Although the above has been described with respect to LM wells being formed adjacent to a package substrate, i.e., with a package having the LM and a socket having pins to fit into the wells and form electrical connections via the LM, embodiments herein can be implemented in a reverse manner, i.e., with a package that has pins and a socket that includes the LM in wells as shown in FIG. 1B.

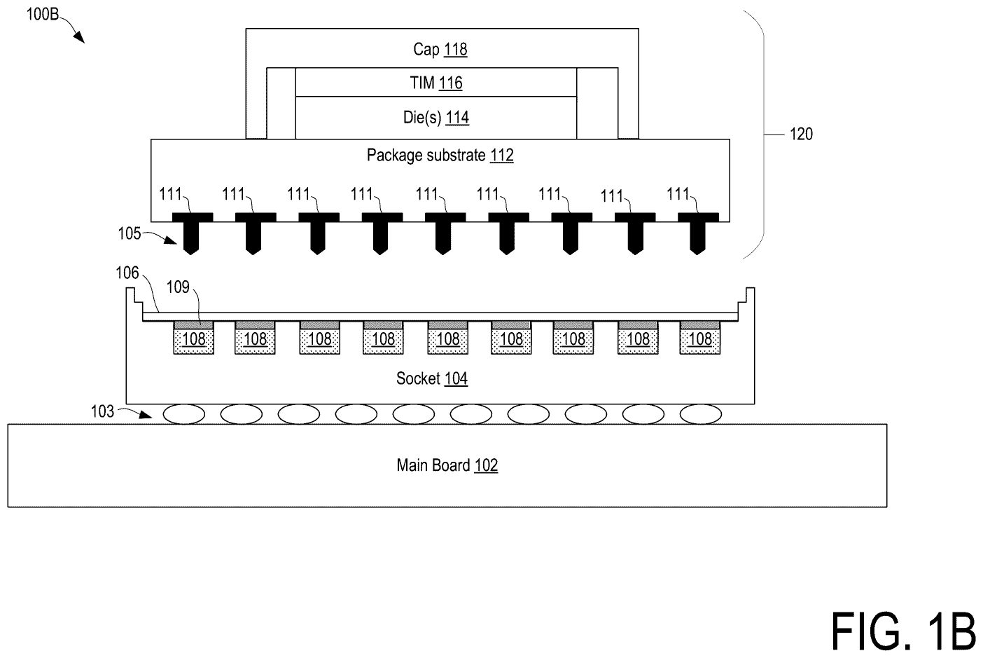

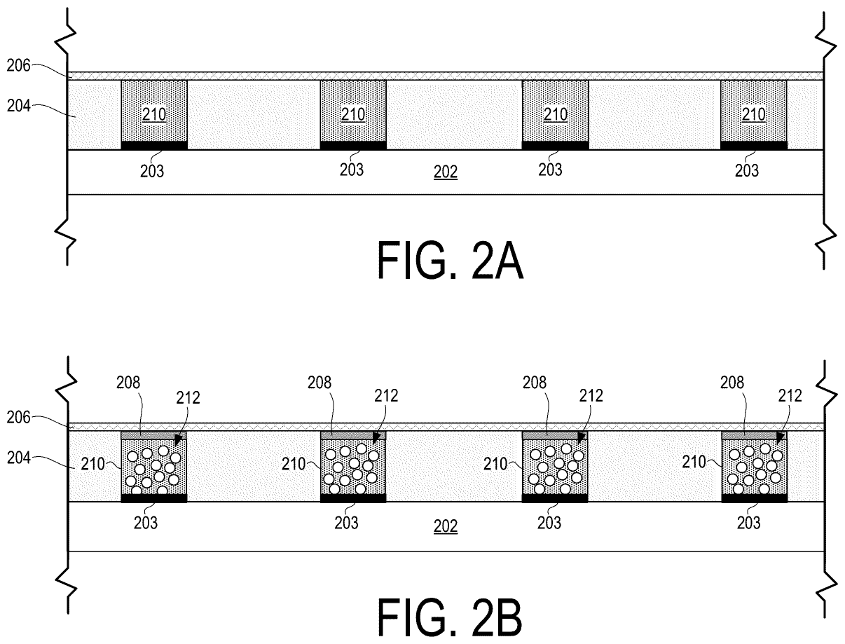

FIGS. 2A-2B illustrate an example LM well implementation in current LM socket interconnects (FIG. 2A) compared with an example LM well implementation in accordance with embodiments of the present disclosure (FIG. 2B). In each example, wells are formed within a layer 204 on a substrate 202. The substrate 202 may be, for example, a package substrate such as package substrate 112 of FIG. 1A, with the layer 204 corresponding to the layer 107 of the interposer 110 of FIG. 1A. Further, each example includes a cap/barrier layer 206 that seals LM 210 within the wells defined by the layer 204. As shown, the example shown in FIG. 2B further includes a liquid passivation layer 208 on the LM 210 in the wells (between the LM 210 and the cap layer 206), and also includes one or more inert filler materials 212 within the well along with the LM 210. These additional aspects of FIG. 2B can provide certain advantages as described above as compared to the implementation shown in FIG. 2A. Although FIG. 2B illustrates both a liquid passivation layer 208 and inert filler material 212 in the LM wells, embodiments herein may include one aspect without the other, i.e., a liquid passivation layer without inert filler material or inert filler material and no liquid passivation layer.

The liquid passivation layer 208 can be implemented using an oil-based material, such as mineral oil, paraffin, paraffinic mineral oil, or Polyalphaolefin oil, as LM has been observed to be inert electrically when in contact with Polyalpaolefin oil. The liquid passivation layer 208 can also be implemented using a wax-based material, such as paraffin wax. In the context of these various implementations, layer 208 may comprise a layer containing carbon. In some implementations, layer 208 may have an atomic composition comprising at least 10% carbon atoms. In some implementations, layer 208 may have an atomic composition comprising at least 20% carbon atoms. The liquid passivation layer material can be sprayed, injected, dipped, or wiped over the surface of interest, e.g., the top of the LM in the well, with the process depending on the thickness of the fluid desired. To mitigate humidity issues, the liquid passivation layer may be only a few nm thick (e.g., less than 5 nm).

The inert filler material 212 can be implemented using desiccants or other materials that can absorb moisture from the surrounding atmosphere, e.g., silica gels or mesoporous particles. The filler material can be mixed with the LM before or after it has been inserted into the wells. For example, the LM and filler can be pre-mixed before, and the mixture can screen printed or injected into the well as part of the LM patch process. In some embodiments, the filler material can be a liquid separate from the LM material that is either pre- or post-filled after the LM is filled into the well.

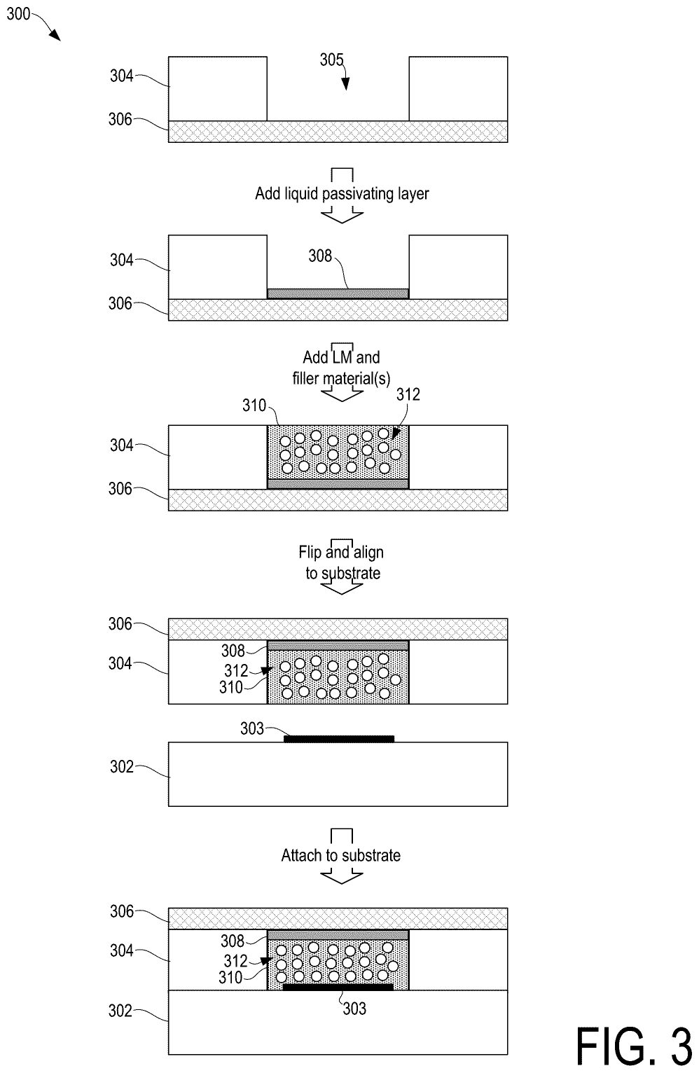

FIG. 3 illustrates an example process 300 for manufacturing an integrated circuit device assembly that utilizes a liquid metal (LM) socket interconnect in accordance with embodiments of the present disclosure. In the example shown, the LM is filled into an interposer housing that is then attached to a substrate (e.g., package substrate such as 112 of FIG. 1A). This may be referred to as a “fill first” approach. The process 300 may include additional, fewer, or other aspects that are not shown.

The process 300 begins with a housing layer 304 formed on a cap/barrier layer 306. The housing layer 304 defines wells 305 into which LM and other materials can be deposited. As shown, a liquid passivating layer 308 is deposited in the well 305, with LM 310 and inert filler material(s) 312 being deposited into the well 305 thereafter. As described above, in some embodiments, the LM 310 and inert filler material(s) 312 can be pre-mixed or can be added in separate steps. The materials can be deposited in the well using the techniques described above (e.g., spraying, printing, injection, etc.) for the respective materials. Once the wells have been filled, the assembly is flipped and aligned to a substrate 302 (e.g., an integrated circuit package substrate), such that conductive pads 303 on the substrate 302 are aligned with the wells. The assembly is then attached to the substrate 302 (e.g., adhesively bonded).

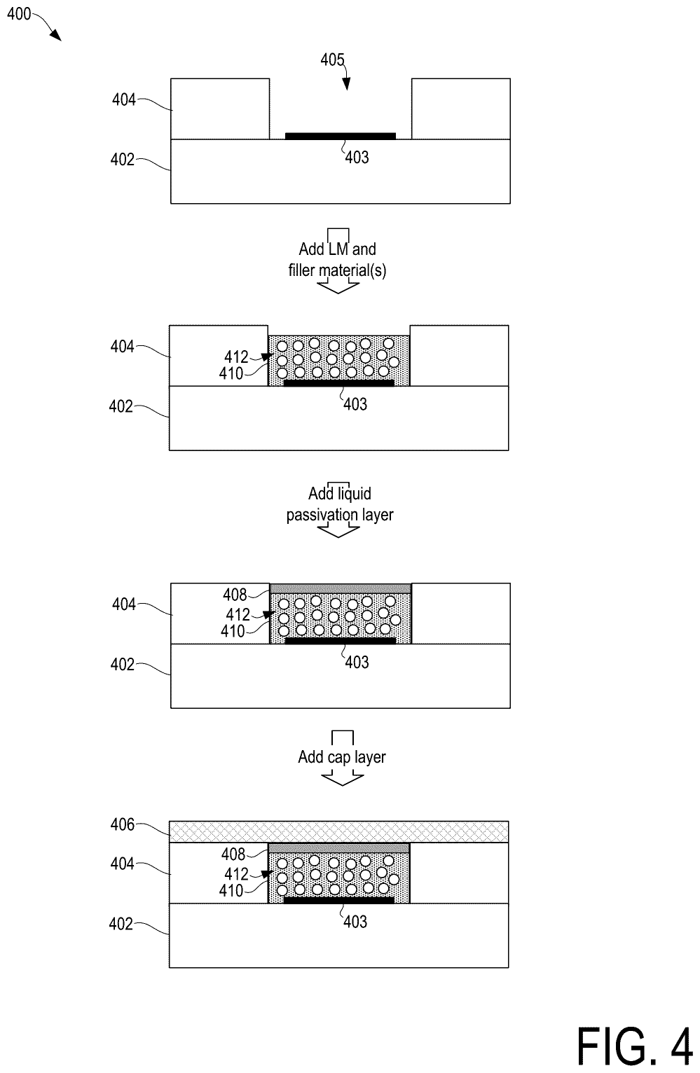

FIG. 4 illustrates another example process 400 for manufacturing an integrated circuit device assembly that utilizes a LM socket interconnect in accordance with embodiments of the present disclosure. In the example shown, in contrast to the process 300 of FIG. 3, the interposer housing is first attached to a substrate (e.g., a package substrate) and is then filled with LM. This may be referred to as a “fill last” approach. The process 400 may include additional, fewer, or other aspects that are not shown.

The process 400 beings with a housing layer 404 coupled to a substrate 402 (e.g., an integrated circuit package substrate) with conductive pads 403. The housing layer 404 defines wells 405 that are aligned with the conductive pads 403 as shown. Next, LM 410 and inert filler material(s) 412 are deposited into the well 405. As described above, in some embodiments, the LM 310 and inert filler material(s) 312 can be pre-mixed or can be added in separate steps. A liquid passivation layer 408 is then formed on the LM/filler material mixture in the well 405 as shown. The materials can be deposited in the well using the techniques described above (e.g., spraying, printing, injection, etc.) for the respective materials. Finally, a cap/barrier layer 406 is added to seal the materials within the wells.

Although the above has been described with respect to LM-based interconnections between a main board and an integrated circuit package substrate that includes one or more integrated circuit dies, aspects of the present disclosure can be implemented for LM-based interconnections between other components as well, e.g., between a package substrate and an integrated circuit die.

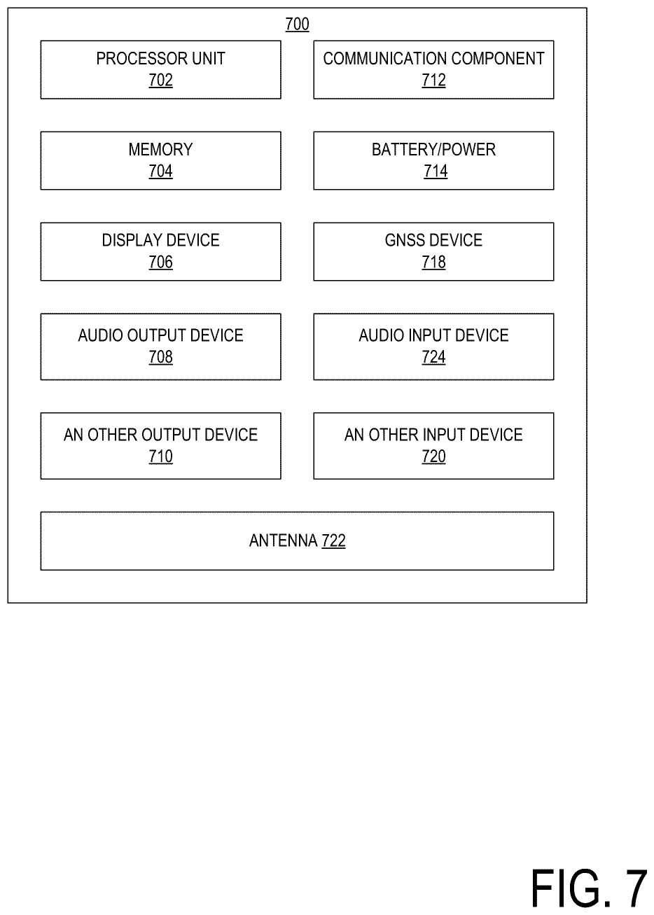

FIG. 5 is a top view of a wafer 500 and dies 502 that may incorporate any of the embodiments disclosed herein. The wafer 500 may be composed of semiconductor material and may include one or more dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The die 502 may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 702 of FIG. 7) or other logic that is configured to store information in the memory devices or execute instructions stored in the memory array.

FIG. 6 is a cross-sectional side view of an integrated circuit device 600 that may be included in any of the embodiments disclosed herein. One or more of the integrated circuit devices 600 may be included in one or more dies 502 (FIG. 5). The integrated circuit device 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit device 600 may be used. The die substrate 602 may be part of a singulated die (e.g., the dies 502 of FIG. 5) or a wafer (e.g., the wafer 500 of FIG. 5).

The integrated circuit device 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 6, a transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit device 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit devices having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit device 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit device 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit device 600 with another component (e.g., a printed circuit board or a package substrate, e.g., 112). The integrated circuit device 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit device 600 is a double-sided die, the integrated circuit device 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit device 600 from the conductive contacts 636.

In other embodiments in which the integrated circuit device 600 is a double-sided die, the integrated circuit device 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit device 600 from the conductive contacts 636. In some embodiments, TSVs extending through the substrate can be used for routing power and ground signals from conductive contacts on the opposite side of the integrated circuit device 600 from the conductive contacts 636 to the transistors 640 and any other components integrated into the die 600, and the metallization stack 619 can be used to route I/O signals from the conductive contacts 636 to transistors 640 and any other components integrated into the die 600.

Multiple integrated circuit devices 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 7 is a block diagram of an example electrical device 700 that may include one or more of the embodiments disclosed herein. For example, any suitable ones of the components of the electrical device 700 may include one or more of assemblies 100, integrated circuit devices 600, or integrated circuit dies 502 disclosed herein. A number of components are illustrated in FIG. 7 as included in the electrical device 700, but any one or more of these components may be omitted or duplicated, as suitable for the application. In some embodiments, some or all of the components included in the electrical device 700 may be attached to one or more motherboards mainboards, or system boards. In some embodiments, one or more of these components are fabricated onto a single system-on-a-chip (SoC) die.

Additionally, in various embodiments, the electrical device 700 may not include one or more of the components illustrated in FIG. 7, but the electrical device 700 may include interface circuitry for coupling to the one or more components. For example, the electrical device 700 may not include a display device 706, but may include display device interface circuitry (e.g., a connector and driver circuitry) to which a display device 706 may be coupled. In another set of examples, the electrical device 700 may not include an audio input device 724 or an audio output device 708, but may include audio input or output device interface circuitry (e.g., connectors and supporting circuitry) to which an audio input device 724 or audio output device 708 may be coupled.

The electrical device 700 may include one or more processor units 702 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 702 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 700 may include a memory 704, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 704 may include memory that is located on the same integrated circuit die as the processor unit 702. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 700 can comprise one or more processor units 702 that are heterogeneous or asymmetric to another processor unit 702 in the electrical device 700. There can be a variety of differences between the processing units 702 in a system in terms of a spectrum of metrics of merit including architectural, microarchitectural, thermal, power consumption characteristics, and the like. These differences can effectively manifest themselves as asymmetry and heterogeneity among the processor units 702 in the electrical device 700.

In some embodiments, the electrical device 700 may include a communication component 712 (e.g., one or more communication components). For example, the communication component 712 can manage wireless communications for the transfer of data to and from the electrical device 700. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 712 may operate in accordance with other wireless protocols in other embodiments. The electrical device 700 may include an antenna 722 to facilitate wireless communications and/or to receive other wireless communications (such as AM or FM radio transmissions).

In some embodiments, the communication component 712 may manage wired communications, such as electrical, optical, or any other suitable communication protocols (e.g., IEEE 802.3 Ethernet standards). As noted above, the communication component 712 may include multiple communication components. For instance, a first communication component 712 may be dedicated to shorter-range wireless communications such as Wi-Fi or Bluetooth, and a second communication component 712 may be dedicated to longer-range wireless communications such as global positioning system (GPS), EDGE, GPRS, CDMA, WiMAX, LTE, EV-DO, or others. In some embodiments, a first communication component 712 may be dedicated to wireless communications, and a second communication component 712 may be dedicated to wired communications.

The electrical device 700 may include battery/power circuitry 714. The battery/power circuitry 714 may include one or more energy storage devices (e.g., batteries or capacitors) and/or circuitry for coupling components of the electrical device 700 to an energy source separate from the electrical device 700 (e.g., AC line power).

The electrical device 700 may include a display device 706 (or corresponding interface circuitry, as discussed above). The display device 706 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 700 may include an audio output device 708 (or corresponding interface circuitry, as discussed above). The audio output device 708 may include any embedded or wired or wirelessly connected external device that generates an audible indicator, such speakers, headsets, or earbuds.

The electrical device 700 may include an audio input device 724 (or corresponding interface circuitry, as discussed above). The audio input device 724 may include any embedded or wired or wirelessly connected device that generates a signal representative of a sound, such as microphones, microphone arrays, or digital instruments (e.g., instruments having a musical instrument digital interface (MIDI) output). The electrical device 700 may include a Global Navigation Satellite System (GNSS) device 718 (or corresponding interface circuitry, as discussed above), such as a Global Positioning System (GPS) device. The GNSS device 718 may be in communication with a satellite-based system and may determine a geolocation of the electrical device 700 based on information received from one or more GNSS satellites, as known in the art.

The electrical device 700 may include another output device 710 (or corresponding interface circuitry, as discussed above). Examples of the other output device 710 may include an audio codec, a video codec, a printer, a wired or wireless transmitter for providing information to other devices, or an additional storage device.

The electrical device 700 may include another input device 720 (or corresponding interface circuitry, as discussed above). Examples of the other input device 720 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 700 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 700 may be any other electronic device that processes data. In some embodiments, the electrical device 700 may comprise multiple discrete physical components. Given the range of devices that the electrical device 700 can be manifested as in various embodiments, in some embodiments, the electrical device 700 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising: a substrate comprising conductive contacts on a first side of the substrate; a housing coupled to the first side of the substrate, the housing defining a set of holes around the conductive contacts; Gallium-based liquid metal in each hole defined by the housing, the liquid metal in contact with the conductive contact in the hole; and a layer of material on a surface of the liquid metal in each hole, the layer of material on an opposite end of the hole from the conductive contact in the hole, the layer of material having an atomic composition of at least 10% carbon.

Example 2 includes the subject matter of Example 1, wherein the layer of material comprises a passivation layer.

Example 3 includes the subject matter of Example 1 or 2, wherein the layer of material comprises one or more of mineral oil, paraffinic oil, and Polyalphaolefin oil.

Example 4 includes the subject matter of Example 1 or 2, wherein the layer of material comprises paraffin wax.

Example 5 includes the subject matter of any one of Examples 1-4, further comprising an inert material in the holes, the inert material below the layer of material.

Example 6 includes the subject matter of Example 5, wherein the inert material is a desiccant.

Example 7 includes the subject matter of Example 5 or 6, wherein the inert material includes one or more of silica gel and mesoporous particles.

Example 8 includes the subject matter of any one of Examples 1-7, wherein the layer of material comprises a first layer, the apparatus further comprising a second layer enclosing the liquid metal and the first layer within the holes.

Example 9 includes the subject matter of any one of Examples 1-8, further comprising an integrated circuit die coupled to the substrate via the first conductive contacts.

Example 10 includes the subject matter of any one of Examples 1-9, further comprising: a thermal interface material on the integrated circuit die; and a cap coupled to the second side of the substrate, wherein the integrated circuit die and the thermal interface material are between the cap and the second side of the substrate.

Example 11 is an apparatus comprising: a substrate comprising conductive contacts on a first side of the substrate; a housing coupled to the first side of the substrate, the housing defining a set of holes around the conductive contacts; Gallium-based liquid metal in each hole defined by the housing, the liquid metal in contact with the conductive contact in the hole; an inert material in each hole defined by the housing; and a layer enclosing the liquid metal and the inert material in the holes.

Example 12 includes the subject matter of Example 11, wherein the inert material is a desiccant.

Example 13 includes the subject matter of Example 11 or 12, wherein the inert material includes one or more of silica gel and mesoporous particles.

Example 14 includes the subject matter of any one of Examples 11-13, further comprising a passivation layer on a surface of the liquid metal, the passivation layer on an opposite end of the hole from the conductive contact in the hole

Example 15 includes the subject matter of Example 14, wherein the passivation layer comprises an oil-based material or a wax-based material.

Example 16 includes the subject matter of Example 15, wherein the passivation layer comprises one or more of mineral oil, paraffinic oil, and Polyalphaolefin oil.

Example 17 includes the subject matter of Example 14, wherein the passivation layer comprises paraffin wax.

Example 18 includes the subject matter of any one of Examples 11-17, further comprising an integrated circuit die coupled to the substrate via the first conductive contacts.

Example 19 includes the subject matter of any one of Examples 11-18, further comprising: a thermal interface material on the integrated circuit die; and a cap coupled to the second side of the substrate, wherein the integrated circuit die and the thermal interface material are between the cap and the second side of the substrate.

Example 20 is a system comprising: a main board; a socket coupled to the main board, the socket comprising a set of pins extending from the socket in a direction opposite the main board; an integrated circuit device assembly coupled to the socket, the integrated circuit device assembly comprising: a substrate comprising conductive contacts on a first side of the substrate; an integrated circuit die coupled to a second side of the substrate opposite the first side; a housing coupled to the first side of the substrate, the housing defining a set of holes around the conductive contacts; Gallium-based liquid metal in the holes defined by the housing, the liquid metal in contact with the conductive contacts; an inert material in the holes; and a passivation layer at an end of the hole opposite from the conductive contact of the substrate; wherein the pins of the socket are in contact with the liquid metal in the holes.

Example 21 includes the subject matter of Example 20, wherein the passivation layer comprises an oil-based material or a wax-based material.

Example 22 includes the subject matter of Example 21, wherein the passivation layer comprises one or more of mineral oil, paraffinic oil, and Polyalphaolefin oil.

Example 23 includes the subject matter of Example 20, wherein the passivation layer comprises paraffin wax.

Example 24 includes the subject matter of Example 20, wherein the inert material is a desiccant.

Example 25 includes the subject matter of Example 20 or 24, wherein the inert material includes one or more of silica gel and mesoporous particles.

Example 26 includes the subject matter of any one of Examples 20-25, further comprising a layer enclosing the liquid metal, inert material, and liquid passivation layer within the holes.

Example 27 includes the subject matter of any one of Examples 20-26, wherein the integrated circuit device assembly further comprises: a thermal interface material on the integrated circuit die; and a cap coupled to the second side of the substrate, wherein the integrated circuit die and the thermal interface material are between the cap and the second side of the substrate.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An apparatus comprising:
a substrate comprising conductive contacts on a first side of the substrate;
a housing coupled to the first side of the substrate, the housing defining a set of holes around the conductive contacts;
Gallium-based liquid metal in each hole defined by the housing, the liquid metal in contact with the conductive contact in the hole; and
a layer of material on a surface of the liquid metal in each hole, the layer on an opposite end of the hole from the conductive contact in the hole, the material having an atomic composition of at least 10% carbon.

2. The apparatus of claim 1, wherein the layer of material comprises a passivation layer.

3. The apparatus of claim 1, wherein the layer of material comprises one or more of mineral oil, paraffinic oil, and Polyalphaolefin oil.

4. The apparatus of claim 1, wherein the passivation layer comprises paraffin wax.

5. The apparatus of claim 1, further comprising an inert material in the holes, the inert material below the layer of material.

6. The apparatus of claim 5, wherein the inert material is a desiccant.

7. The apparatus of claim 5, wherein the inert material includes one or more of silica gel and mesoporous particles.

8. The apparatus of claim 1, wherein the layer of material comprises a first layer, the apparatus further comprising a second layer enclosing the liquid metal and the first layer within the holes.

9. The apparatus of claim 1, further comprising an integrated circuit die coupled to the substrate via the first conductive contacts.

10. An apparatus comprising:
a substrate comprising conductive contacts on a first side of the substrate;
a housing coupled to the first side of the substrate, the housing defining a set of holes around the conductive contacts;
Gallium-based liquid metal in each hole defined by the housing, the liquid metal in contact with the conductive contact in the hole;
an inert material in each hole defined by the housing; and
a layer enclosing the liquid metal and the inert material in the holes.

11. The apparatus of claim 10, wherein the inert material is a desiccant.

12. The apparatus of claim 10, wherein the inert material includes one or more of silica gel and mesoporous particles.

13. The apparatus of claim 10, further comprising a passivation layer on a surface of the liquid metal, the passivation layer on an opposite end of the hole from the conductive contact in the hole.

14. The apparatus of claim 13, wherein the passivation layer comprises an oil-based material or a wax-based material.

15. The apparatus of claim 14, wherein the passivation layer comprises one or more of mineral oil, paraffinic oil, and Polyalphaolefin oil.

16. The apparatus of claim 14, wherein the passivation layer comprises paraffin wax.

17. The apparatus of claim 10, further comprising an integrated circuit die coupled to the substrate via the first conductive contacts.

18. A system comprising:
a main board;
a socket coupled to the main board, the socket comprising a set of pins extending from the socket in a direction opposite the main board;
an integrated circuit device assembly coupled to the socket, the integrated circuit device assembly comprising:
a substrate comprising conductive contacts on a first side of the substrate;
an integrated circuit die coupled to a second side of the substrate opposite the first side;
a housing coupled to the first side of the substrate, the housing defining a set of holes around the conductive contacts;
Gallium-based liquid metal in the holes defined by the housing, the liquid metal in contact with the conductive contacts;
an inert material in the holes; and
a passivation layer at an end of the hole opposite from the conductive contact of the substrate;
wherein the pins of the socket are in contact with the liquid metal in the holes.

19. The system of claim 18, wherein the passivation layer comprises an oil-based material or a wax-based material.

20. The system of claim 18, wherein the inert material is a desiccant.
